(19) United States
(12) Patent Application Publication
(10) Pub. No.: US 2024/0224629 A1
(43) Pub. Date: Jul. 4, 2024

(54) DISPLAY PANEL AND MANUFACTURING METHOD THEREOF, AND DISPLAY DEVICE

(71) Applicant: Shenzhen China Star Optoelectronics Semiconductor Display Technology Co., Ltd., Shenzhen (CN)

(72) Inventor: Qianyi ZHANG, Shenzhen (CN)

(21) Appl. No.: 18/509,344

(22) Filed: Nov. 15, 2023

(30) Foreign Application Priority Data
Dec. 28, 2022 (CN) 202211698231.5

(51) Int. Cl. H10K 59/126; H10K 59/12; H10K 59/131; H10K 59/80

(52) U.S. Cl. CPC H10K 59/126; H10K 59/1201; H10K 59/131; H10K 59/87; H10K 2102/351

(57) ABSTRACT

A display panel and a manufacturing method thereof, and a display device are provided. The display panel includes a display area and a non-display area disposed adjacent to the display area, and includes a substrate, and a thin-film transistor layer, a passivation layer, a planarization layer, a protective layer, and an anode that are disposed and stacked on the substrate; the thin-film transistor layer includes a wiring portion disposed in the non-display area, and an orthographic projection of the protective layer on the thin-film transistor layer at least covers the wiring portion. By providing the protective layer between the planarization layer and the anode, the anode is thereby prevented from contacting with foreign matters on the planarization layer, alleviating a risk of dark spots appearing on the display panel.

### CROSS-REFERENCE TO RELATED APPLICATION

This application claims priority to Chinese Patent Application No. 202211698231.5, filed on Dec. 28, 2022, the disclosure of which is incorporated herein by reference in its entirety.

### TECHNICAL FIELD

The present disclosure relates to the field of display technologies, and in particular, to a display panel and a manufacturing method thereof, and a display device.

### BACKGROUND OF INVENTION

An organic light-emitting diode (OLED) display panel is a display device different from a conventional liquid crystal display (LCD). The OLED display panel has advantages, such as active light emission, good temperature performance, low power consumption, fast response, bendable, ultra-thin, and low-cost, and becomes a mainstream technology for a next-generation display drive backplane.

The OLED display panel includes a thin-film transistor (TFT) device and an OLED device. The OLED display panel includes a passivation layer, a planarization layer, an anode, a light-emitting layer and a cathode. In a manufacturing process of the OLED device, surface roughness of the planarization layer may be degraded, thereby affecting the anode deposited on the planarization layer, causing dark spots appearing on a pixel unit, and further affecting display effect of the display panel.

### SUMMARY OF INVENTION

Embodiments of the present disclosure provide a display panel and a manufacturing method thereof, and a display device, to alleviate defects in the related art.

In order to implement the foregoing objectives, technical solutions provided in the embodiments of the present disclosure are as follows.

An embodiment of the present disclosure provides a display panel, including a display area and a non-display area disposed adjacent to the display area; and the display panel includes:
a substrate;
a thin-film transistor layer, disposed on the substrate;
a passivation layer, disposed on the thin-film transistor layer;
a planarization layer, disposed on a side of the passivation layer away from the thin-film transistor layer;
a protective layer, disposed on a side of the planarization layer away from the passivation layer; and
an anode, disposed on a side of the protective layer away from the planarization layer; and
in the display panel provided by the embodiment, an orthographic projection of the protective layer on the thin-film transistor layer at least overlaps a portion of an orthographic projection of the anode on the thin-film transistor layer.

In the display panel provided by the embodiment of the present disclosure, the thin-film transistor layer includes a wiring portion disposed in the non-display area; the protective layer includes a first protective layer and a second protective layer disposed at intervals; and the first protective layer is disposed in the display area, and the second protective layer is disposed in the non-display area; and an orthographic projection of the first protective layer on the thin-film transistor layer at least overlaps a portion of the orthographic projection of the anode on the thin-film transistor layer, and an orthographic projection of the second protective layer on the thin-film transistor layer covers the wiring portion.

In the display panel provided by the embodiment of the present disclosure, the thin-film transistor layer includes an active layer, a gate insulation layer, a gate electrode, an interlayer insulation layer, a source electrode, and a drain electrode that are disposed and stacked on the substrate; and the anode includes an overlapping portion and a connecting portion disposed at a peripheral side of the overlapping portion, an orthographic projection of the overlapping portion on the thin-film transistor layer is located within or coincides with the orthographic projection of the first protective layer on the thin-film transistor layer, and the connecting portion is connected to the source electrode or the drain electrode.

In the display panel provided by the embodiment of the present disclosure, the thin-film transistor layer includes a gate electrode, a gate insulation layer, an active layer, a source electrode, and a drain electrode that are disposed and stacked on the substrate 10; and the orthographic projection of the first protective layer on the thin-film transistor layer is located within or coincides with the orthographic projection of the anode on the thin-film transistor layer, and the first protective layer is connected to the source electrode or the drain electrode.

In the display panel provided by the embodiment of the present disclosure, a side of the first protective layer close to the planarization layer is flush with a side of the first protective layer close to the anode.

In the display panel provided by the embodiment of the present disclosure, the protective layer is made of an inert material; and the inert material is at least one selected from the group consisting of a molybdenum-titanium-nickel compound, a titanium metal, an indium gallium titanium oxide, and a zinc oxide.

In the display panel provided by the embodiment of the present disclosure, a thickness of the protective layer is greater than or equal to 100 angstroms and less than or equal to 400 angstroms.

An embodiment of the present disclosure provides a manufacturing method of a display panel; the display panel includes a display area and a non-display area disposed adjacent to the display area, and the manufacturing method of the display panel includes steps as follows:
providing a substrate;
forming a thin-film transistor layer on the substrate;
sequentially forming a passivation layer and a planarization layer on a side of the thin-film transistor layer away from the substrate;
forming a protective layer on a side of the planarization layer away from the passivation layer; and
forming an anode on a side of the protective layer away from the planarization layer;
in the display panel of the present embodiment, an orthographic projection of the anode on the thin-film transistor layer at least overlaps a portion of an orthographic projection of the protective layer on the thin-film transistor layer.

In the manufacturing method provided in the present embodiment of the present disclosure, the display area includes a light-emitting area and a non-light-emitting area disposed adjacent to the light-emitting area; and the forming the protective layer on the side of the planarization layer away from the passivation layer includes steps as follows:
forming an electrode layer on a side of the planarization layer away from the passivation layer;
manufacturing a photoresist layer on the electrode layer;
exposing the photoresist layer by using a first halftone mask, and then developing the photoresist layer to form a first photoresist sub-layer and a second photoresist sub-layer, where the first photoresist sub-layer is disposed in the non-display area, and the second photoresist sub-layer is disposed in the light-emitting area;
using the first photoresist sub-layer and the second photoresist sub-layer as a shielding layer, and etching a portion of the electrode layer not shielded by the shielding layer to form a first protective layer and a second protective layer, where the first protective layer is disposed to correspond to the first photoresist sub-layer, and the second protective layer is disposed to correspond to the second photoresist sub-layer; and
peeling off the first photoresist sub-layer and the second photoresist sub-layer.

An embodiment of the present disclosure provides a display device comprising a display panel, wherein the display panel comprises a display area and a non-display area disposed adjacent to the display area, and the display panel further comprises:
a substrate;
a thin-film transistor layer, disposed on the substrate;
a passivation layer, disposed on the thin-film transistor layer;
a planarization layer, disposed on a side of the passivation layer away from the thin-film transistor layer;
a protective layer, disposed on a side of the planarization layer away from the passivation layer; and
an anode, disposed on a side of the protective layer away from the planarization layer; and
wherein an orthographic projection of the protective layer on the thin-film transistor layer at least overlaps a portion of an orthographic projection of the anode on the thin-film transistor layer.

In the display device provided by the embodiment of the present disclosure, the thin-film transistor layer comprises a wiring portion disposed in the non-display area;
wherein the protective layer comprises a first protective layer and a second protective layer disposed at intervals; and the first protective layer is disposed in the display area, and the second protective layer is disposed in the non-display area; and
wherein an orthographic projection of the first protective layer on the thin-film transistor layer at least overlaps a portion of the orthographic projection of the anode on the thin-film transistor layer, and an orthographic projection of the second protective layer on the thin-film transistor layer covers the wiring portion.

In the display device provided by the embodiment of the present disclosure, the thin-film transistor layer comprises an active layer, a gate insulation layer, a gate electrode, an interlayer insulation layer, a source electrode, and a drain electrode that are disposed and stacked on the substrate; and
wherein the anode comprises an overlapping portion and a connecting portion disposed at a peripheral side of the overlapping portion, an orthographic projection of the overlapping portion on the thin-film transistor layer is located within or coincides with the orthographic projection of the first protective layer on the thin-film transistor layer, and the connecting portion is connected to the source electrode or the drain electrode.

In the display device provided by the embodiment of the present disclosure, the thin-film transistor layer comprises a gate electrode, a gate insulation layer, an active layer, a source electrode, and a drain electrode that are disposed and stacked on the substrate; and
wherein the orthographic projection of the first protective layer on the thin-film transistor layer is located within or coincides with the orthographic projection of the anode on the thin-film transistor layer, and the first protective layer is connected to the source electrode or the drain electrode.

In the display device provided by the embodiment of the present disclosure, a side of the first protective layer close to the planarization layer is flush with a side of the first protective layer close to the anode.

In the display device provided by the embodiment of the present disclosure, the protective layer is made of an inert material; and the inert material is at least one selected from the group consisting of a molybdenum-titanium-nickel compound, a titanium metal, an indium gallium titanium oxide, and a zinc oxide.

In the display device provided by the embodiment of the present disclosure, a thickness of the protective layer is greater than or equal to 100 angstroms and less than or equal to 400 angstroms.

Beneficial Effects of the embodiments of the present disclosure are as follows: the embodiments of the present disclosure provide the display panel and the manufacturing method thereof, and the display device. The display panel includes the display area and the non-display area disposed adjacent to the display area; the display panel includes the substrate, and the thin-film transistor layer, the passivation layer, the planarization layer, the protective layer, and the anode that are disposed and stacked on the substrate; the thin-film transistor layer includes the wiring portion disposed in the non-display area, and the orthographic projection of the protective layer on the thin-film transistor layer at least covers the wiring portion. By providing the protective layer between the planarization layer and the anode and making the orthographic projection of the protective layer on the thin-film transistor layer at least overlaps the portion of the orthographic projection of the anode on the thin-film transistor layer, the anode is thereby prevented from contacting with foreign matters on the planarization layer, alleviating a risk of dark spots appearing on the display panel.

### BRIEF DESCRIPTION OF THE DRAWINGS

In order to more clearly illustrate the technical solutions in the embodiments of the present disclosure, the accompanying drawings that need to be used in the description of the embodiments are briefly described below. Apparently, the accompanying drawings in the following description are merely some embodiments of the present disclosure, and for those skilled in the art, other drawings may be obtained according to these drawings without involving any inventive effort.

FIG. 1 is a schematic diagram of a first cross-sectional view of a display panel according to an embodiment of the present disclosure.

FIG. 2 is a schematic diagram of a second cross-sectional view of a display panel according to an embodiment of the present disclosure.

FIG. 3 is a flowchart of a manufacturing method of a display panel according to an embodiment of the present disclosure.

FIG. 4A to FIG. 4G are schematic structural diagrams of a process of the manufacturing method of the display panel in FIG. 3.

### DETAILED DESCRIPTION OF PREFERRED EMBODIMENTS

The technical solutions in the embodiments of the present disclosure will be clearly and completely described below with reference to the accompanying drawings in the embodiments of the present disclosure. Apparently, the described embodiments are merely some of the embodiments of the present disclosure and are not all of the embodiments. Based on the embodiments of the present disclosure, all other embodiments obtained by those skilled in the related art without creative efforts shall fall within the scope of the protection of the present disclosure. In addition, it should be understood that specific implementation modes of the embodiments described herein are merely used to illustrate and explain the present disclosure, and are not intended to limit the present disclosure. In the present disclosure, in the case that an opposite description is not made, the used terms such as “upper” and “lower” generally refer to an upper portion and a lower portion of the device in an actual use or working state; specially, the terms refer to a plane direction illustrated in the accompanying drawings; and terms of “inner” and “outer” refer to an outline of the device.

Embodiments of the present disclosure provide a display panel and a manufacturing method thereof, and a display device. The following describe details of the embodiments respectively. It should be noted that an order of the following description for the embodiments is not limited to an illustrated order of the embodiments.

The technical solutions of the present disclosure are described with reference to the illustrated embodiments.

### Embodiment 1

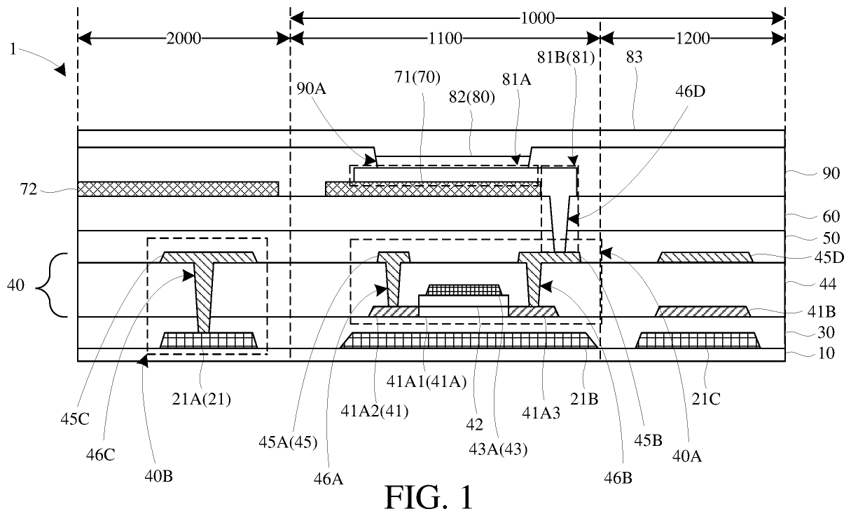

With reference to FIG. 1, FIG. 1 is a schematic cross-sectional view of a display panel according to an embodiment of the present disclosure.

The present embodiment provides a display panel 1, including but not limited to an organic light-emitting diode (OLED) display panel, but the present embodiment is not limited thereto. It should be noted that the present embodiment describes the technical solution of the present disclosure by taking the display panel as an organic light-emitting diode display panel as an example.

In the present embodiment, the display panel 1 includes a display area 1000 and a non-display area 2000 disposed adjacent to the display area 1000; the display panel 1 includes a substrate 10, a thin-film transistor layer 40 containing a thin-film transistor 40A disposed on the substrate 10, a passivation layer 50 disposed on a side of the thin-film transistor layer 40 away from the substrate 10, a planarization layer 60 disposed on a side of the passivation layer 50 away from the thin-film transistor layer 40, a protective layer 70 disposed on a side of the planarization layer 60 away from the passivation layer 50, and an anode 81 disposed on a side of the protective layer 70 away from the planarization layer 60; and an orthographic projection of the protective layer 70 on the thin-film transistor layer 40 at least overlaps a portion of an orthographic projection of the anode 81 on the thin-film transistor layer 40.

It can be understood that, in an existing manufacturing process of a display panel, ashing residues in an ashing process are prone to remaining on a surface of a planarization layer to form foreign matters, thereby affecting an anode deposited on the planarization layer, causing dark spots appearing on a pixel unit, and then affecting display effect of the display panel. In the present embodiment, by providing the protective layer between the planarization layer and the anode and making the orthographic projection of the protective layer on the thin-film transistor layer 40 containing the thin-film transistor 40A at least overlap the portion of the orthographic projection of the anode on the thin-film transistor layer 40 containing the thin-film transistor 40A, the anode is prevented from contacting with the foreign matters on the planarization layer, alleviating a risk of dark spots appearing on the display panel.

Further, in the present embodiment, the display panel 1 includes a light shielding layer 21B and a buffer layer 30 disposed between the substrate 10 and the thin-film transistor layer 40, and the thin-film transistor layer 40 includes an active layer 41A, a gate insulation layer 42, a gate electrode 43A, an interlayer insulation layer 44, a source electrode 45A, and a drain electrode 45B that are disposed and stacked on the substrate 10. Specifically, the thin-film transistor layer 40 includes at least one thin-film transistor 40A, and the thin-film transistor 40A includes the active layer 41A, the gate insulation layer 42, the gate electrode 43A, the interlayer insulation layer 44, the source electrode 45A, and the drain electrode 45B that are disposed and stacked on the substrate 10. The source electrode 45A and the drain electrode 45B are disposed in a same layer and are disposed at intervals; namely, the technical solution of the present disclosure is illustrated by taking the thin-film transistor 40A as a top-gate thin-film transistor as an example.

It should be noted that the buffer layer 30 is disposed on a side of the light shielding layer 21B away from the substrate 10, an orthographic projection of the light shielding layer 21B on the substrate 10 at least covers an orthographic projection of the active layer 41A on the substrate 10, and the light shielding layer 21B may shield lights emitted to the active layer 41A, thereby reducing an increase of a leakage current caused by photo-generated carriers during the lights emitting to the active layer 41A, and further maintaining stability of the thin-film transistor 40A during working.

In the present embodiment, the active layer 41A is made of, but is not limited to, amorphous silicon, polysilicon, or a metal oxide material. In an illustrated embodiment, the active layer 41A is made of the metal oxide; the active layer 41A includes a first conductor portion 41A2, a second conductor portion 41A3, and an active segment 41A1 disposed between the first conductor portion 41A2 and the second conductor portion 41A3; and the source electrode 45A is connected to the first conductor portion 41A2, the drain electrode 45B is connected to the second conductor portion 41A3, and an orthographic projection of the gate electrode 43A on the substrate 10 is disposed to overlap an orthographic projection of the active segment 41A1 on the substrate 10.

The gate insulation layer 42 is made of, but is not limited to, a single-layer silicon nitride (Si₃N₄), a single-layer silicon dioxide (SiO₂), a single-layer silicon oxynitride (SiONₓ), or a double-layer structure containing the above film layers; and the gate insulation layer 42 is disposed to cover the gate electrode 43A, so as to block water and oxygen from the gate electrode 43A, thereby insulating the gate electrode 43A. The passivation layer 50 is made of, but is not limited to, a single-layer Si₃N₄, a single-layer SiO₂, a single-layer SiONₓ, or a double-layer structure containing the above film layers; and the passivation layer 50 is disposed to cover the source electrode 45A, the drain electrode 45B, the active layer 41A, and the gate insulation layer 42, so as to block water and oxygen from the source electrode 45A, the drain electrode 45B, and the active layer 41A, thereby insulating the source electrode 45A, the drain electrode 45B, and the active layer 41A.

The protective layer 70 is made of an inert material, and the inert material includes, but is not limited to, one or more of a molybdenum-titanium-nickel compound, a titanium metal (Ti), an indium gallium titanium oxide (IGTO), and a zinc oxide (ZnO); a thickness of the protective layer 70 is greater than or equal to 100 angstroms and less than or equal to 400 angstroms. In an illustrated embodiment, the thickness of the protective layer 70 is any one of 100 angstroms, 200 angstroms, 300 angstroms, and 400 angstroms.

Further, in the present embodiment, the thin-film transistor layer 40 includes a wiring portion 40B disposed in the non-display area 2000; the protective layer 70 includes a first protective layer 71 and a second protective layer 72 disposed at intervals; and the first protective layer 71 is disposed in the display area 1000, and the second protective layer 72 is disposed in the non-display area 2000. An orthographic projection of the first protective layer 71 on the thin-film transistor layer 40 at least overlaps a portion of the orthographic projection of the anode 81 on the thin-film transistor layer 40, and an orthographic projection of the second protective layer 72 on the thin-film transistor layer 40 covers the wiring portion 40B. In an illustrated embodiment, the anode 81 includes an overlapping portion 81A and a connecting portion 81B disposed at a peripheral side of the overlapping portion 81A, an orthographic projection of the overlapping portion 81A on the thin-film transistor layer 40 is located within or coincides with the orthographic projection of the first protective layer 71 on the thin-film transistor layer 40, and the connecting portion 81B is connected to one of the source electrode 45A and the drain electrode 45B.

In an illustrated embodiment, the display area 1000 includes a light-emitting area 1100 and a non-light-emitting area 1200 disposed adjacent to the light-emitting area 1100; the display panel 1 includes a light-emitting device layer 80 disposed in the light-emitting area 1100; the light-emitting device layer 80 includes the anode 81, a light-emitting layer 82, and a cathode 83 that are disposed and stacked on the first protective layer 71; and the first protective layer 71 is disposed in the light-emitting area 1100.

The display panel 1 includes a first metal layer 21, a second metal layer 41, a third metal layer 43, a fourth metal layer 45, and an electrode layer 70 that are stacked. The electrode layer 70 is the above-mentioned protective layer 70. The first metal layer 21 includes the light shielding layer 21B, a first wiring portion 21A, and a first capacitance electrode 21C that are disposed at intervals; the first wiring portion 21A is disposed in the non-display area 2000, the light shielding layer 21B and the first capacitance electrode 21C are disposed in the display area 1000; the second metal layer 41 includes the active layer 41A and a second capacitance electrode 41B, and an orthographic projection of the second capacitance electrode 41B on the substrate 10 overlaps an orthographic projection of the first capacitance electrode 21C on the substrate 10; the third metal layer 43 includes a second wiring portion 45C, the source electrode 45A, the drain electrode 45B, and a third capacitance electrode 45D that are disposed at intervals; and the second wiring portion 45C is disposed in the non-display area 2000, the second wiring portion 45C is disposed to correspond to the first wiring portion 21A, and an orthographic projection of the third capacitance electrode 45D on the substrate 10 overlaps the orthographic projection of the second capacitance electrode 41B on the substrate 10. Specially, the wiring portion 40B includes the first wiring portion 21A and the second wiring portion 45C, and the electrode layer 70 includes the first protective layer 71 and the second protective layer 72 that are disposed at intervals; and the orthographic projection of the second protective layer 72 on the thin-film transistor layer 40 covers the first wiring portion 21A and the second wiring portion 45C.

It can be understood that, the present embodiment provides the first protective layer 71 disposed between the planarization layer 60 and the anode 81, the orthographic projection of the overlapping portion 81A on the thin-film transistor layer 40 is located within or coincides with the orthographic projection of the first protective layer 71 on the thin-film transistor layer 40, and the connecting portion 81B is connected to one of the source electrode 45A and the drain electrode 45B, so that the first protective layer 71 is capable of filling up a rough landform on a surface of the planarization layer 60, thereby preventing the anode 81 contacting with the foreign matters on the planarization layer 60 and reducing the risk of dark spots appearing on the display panel 1. Meanwhile, the present embodiment sets the orthographic projection of the second protective layer 72 on the thin-film transistor layer 40 to cover the first wiring portion 21A and the second wiring portion 45C, thereby preventing water and oxygen from entering the wiring portion 40B and improving the reliability and service life of the display panel 1.

It should be noted that, in the present embodiment, the display panel 1 further includes a pixel define layer 90 disposed on a side of the protective layer 70 away from the thin-film transistor layer 40, the pixel define layer 90 is provided with a first slot 90A exposing the anode 81, and at least a portion of the light-emitting layer 82 is disposed in the first slot 90A; the light-emitting layer 82 is connected to the anode 81 through the first slot 90A, at least a portion of the cathode 83 is disposed in the first slot 90A, and the cathode 83 is connected to the light-emitting layer 82 through the first slot 90A.

The display panel is 1 further provided with a first through hole 46A, a second through hole 46B, a third through hole 46C, and a fourth through hole 46D. The first through hole 46A passes through the interlayer insulation layer 44 and exposes a portion of the first conductor portion 41A2; the second through hole 46B passes through the interlayer insulation layer 44 and exposes a portion of the second conductor portion 41A3; the third through hole 46C passes through the interlayer insulation layer 44 and the buffer layer 30, and then exposes a portion of the first wiring portion 21A; and the fourth through hole 46D passes through the planarization layer 60 and the passivation layer 50, and then exposes a portion of the drain electrode 45B. The source electrode 45A penetrates the first through hole 46A to connect to the first conductor portion 41A2, the drain electrode 45B penetrates the second through hole 46B to connect to the second conductor portion 41A3, the second wiring portion 45C penetrates the third through hole 46C to connect to the first wiring portion 21A, and the connecting portion 81B penetrates the fourth through hole 46D to connect to the drain electrode 45B.

### Embodiment 2

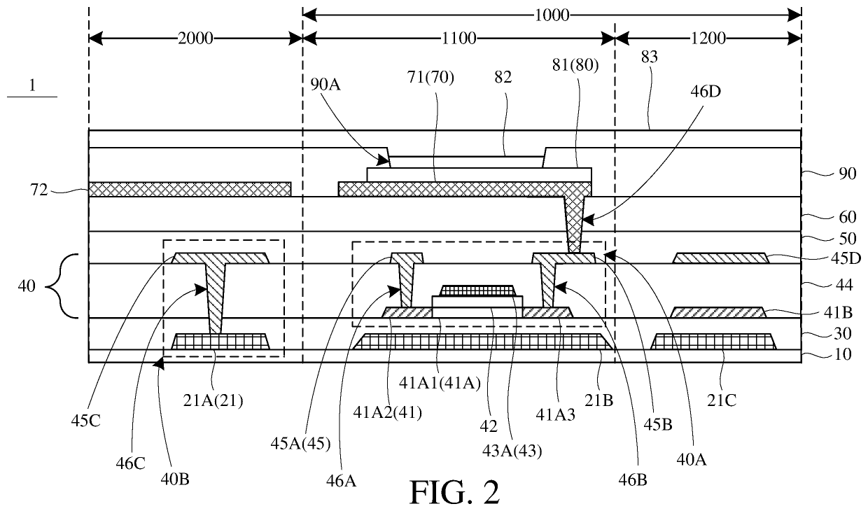

With reference to FIG. 2, FIG. 2 is another schematic cross-sectional view of a display panel according to an embodiment of the present disclosure.

In the present embodiment, a structure of the display panel is similar to/identical to the structure of the display panel provided in the foregoing embodiment; details thereof can refer to the description of the display panel in the foregoing embodiment, which are not described herein again, and differences between the two display panels are as follows.

In the present embodiment, the orthographic projection of the first protective layer 71 on the thin-film transistor layer 40 is located within or coincides with the orthographic projection of the anode 81 on the thin-film transistor layer 40, and the first protective layer 71 is connected to the drain electrode 45B. It can be understood that, in the present embodiment, the orthographic projection of the first protective layer 71 on the thin-film transistor layer 40 is located within or coincides with the orthographic projection of the anode 81 on the thin-film transistor layer 40, which can prevent the anode 81 from contacting with the foreign matters on the planarization layer 60 and further reduce the risk of dark spots appearing on the display panel 1.

### Embodiment 3

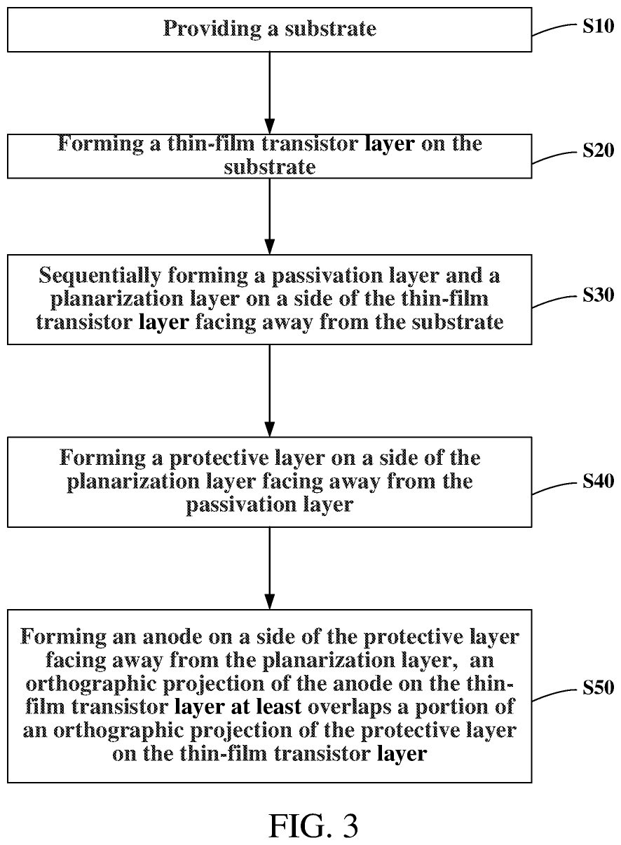

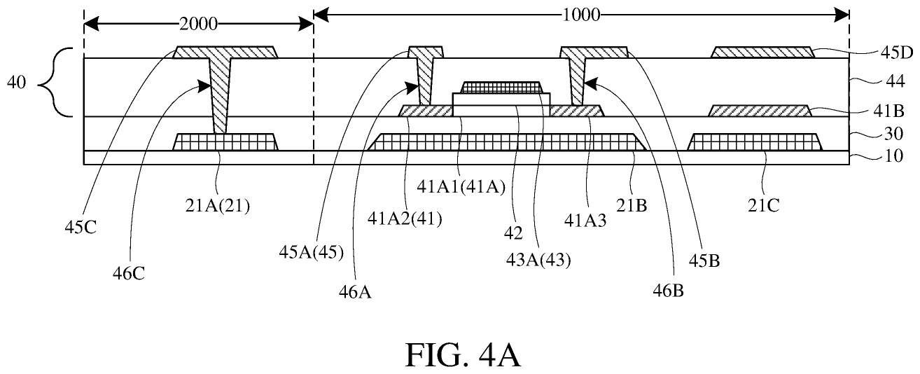

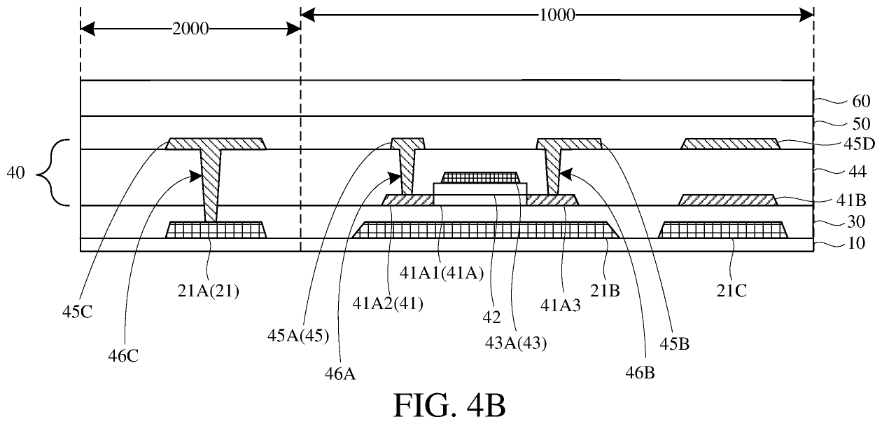

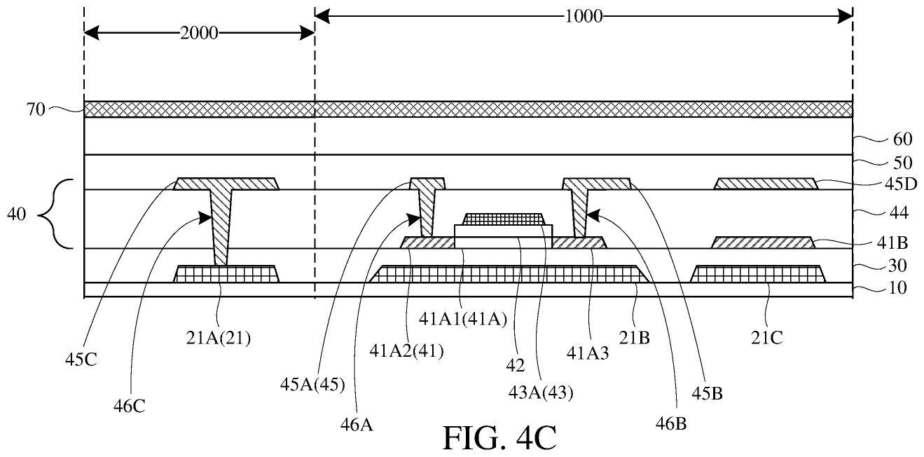

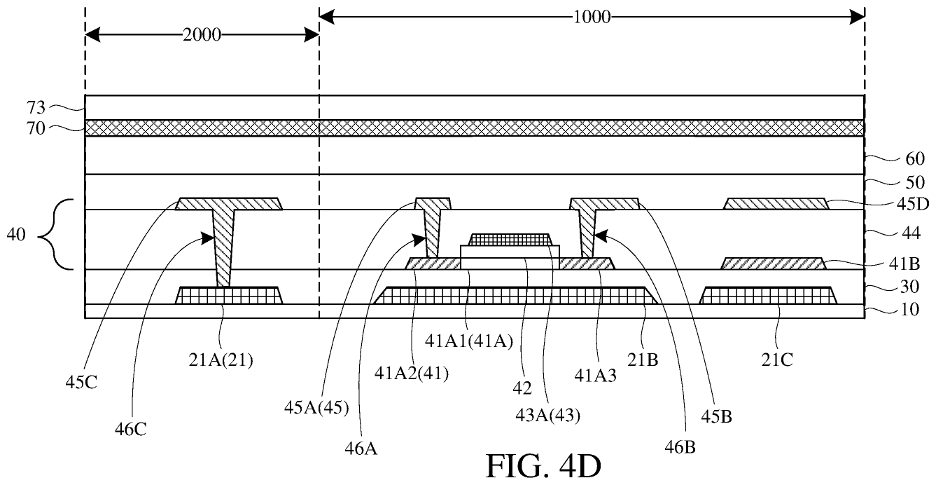

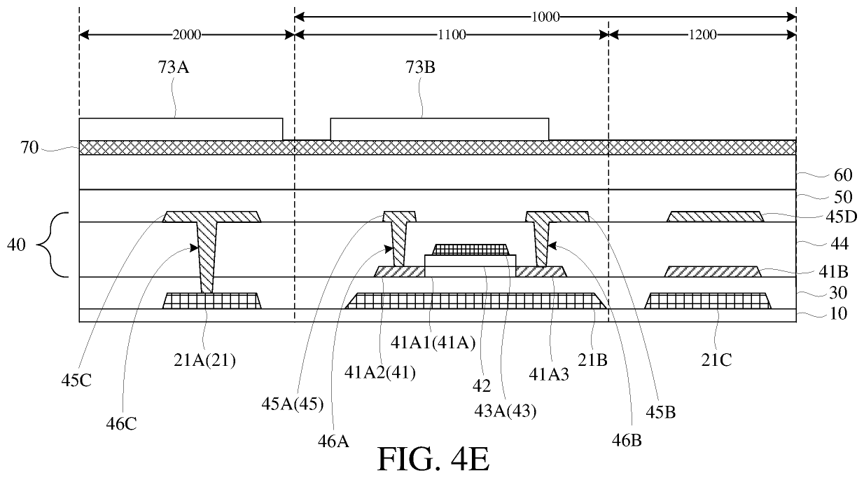

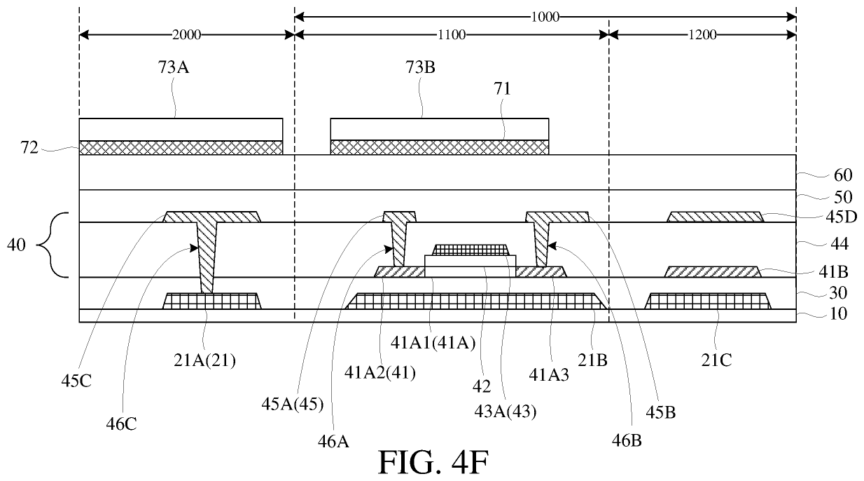

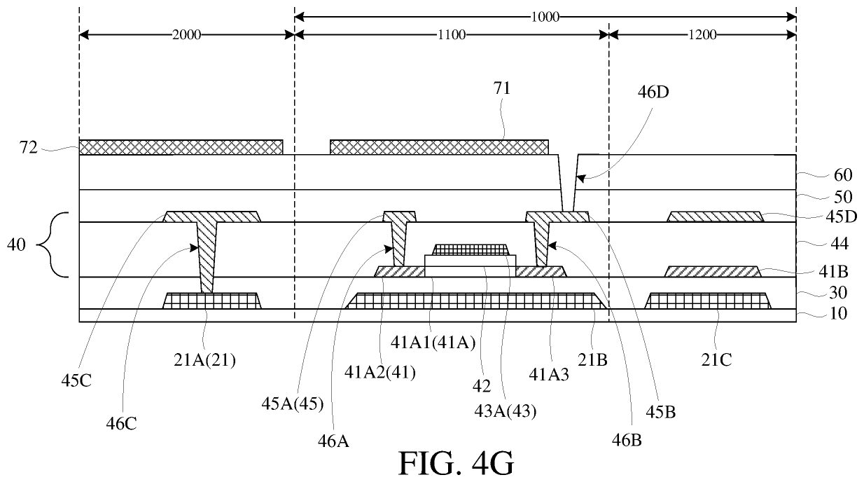

FIG. 3 is a flowchart of a manufacturing method of a display panel according to an embodiment of the present disclosure; and FIG. 4A to FIG. 4G are schematic structural diagrams of a process of the manufacturing method of the display panel in FIG. 3.

In the present embodiment, the display panel 1 includes a display area 1000 and a non-display area 2000 disposed adjacent to the display area 1000, and the manufacturing method of the display panel 1 includes steps as follows.

In step S10, a substrate 10 is provided; when the substrate 10 is a rigid substrate, the substrate 10 is made of metal or glass, and when the substrate 10 is a flexible substrate, the substrate 10 is made of at least one of an acrylic resin, a methacrylic resin, a polyisoprene, a vinyl resin, an epoxy resin, a polyurethane-based resin, a cellulose resin, a silicone resin, a polyimide-based resin, and a polyamide-based resin.

Specifically, the step S10 further includes sequentially forming a first metal layer 21 and a buffer layer 30 on the substrate 10; the first metal layer 21 includes a light shielding layer 21B, a first wiring portion 21A, and a first capacitance electrode 21C that are disposed at intervals; the first wiring portion 21A is disposed in the non-display area 2000, the light shielding layer 21B and the first capacitance electrode 21C are disposed in the display area 1000; the first metal layer 21 is made of, but is not limited to, one mental material or more alloys consisting of molybdenum (Mo), titanium (Ti), and nickel (Ni); and the buffer layer 30 is made of, but is not limited to, a single-layer silicon nitride (Si₃N₄), a single-layer silicon dioxide (SiO₂), a single-layer silicon oxynitride (SiONₓ), or a double-layer structure containing the above film layers.

In step S20, a thin-film transistor layer 40 containing a thin-film transistor 40 is form on the substrate 10, which is as shown in FIG. 4A.

Specifically, step S20 includes sequentially forming a second metal layer 41, a gate insulation layer 42, a third metal layer 43, an interlayer insulation layer 44, and a fourth metal layer 45 on the substrate 10.

The second metal layer 41 includes an active layer 41A and a second capacitance electrode 41B; and the active layer 41A includes an active segment 41A1, a first conductor portion 41A2, and a second conductor portion 41A3. An orthographic projection of a second capacitance electrode 41B on the substrate 10 overlaps an orthographic projection of the first capacitance electrode 21C on the substrate 10. The third metal layer 43 includes a second wiring portion 45C, a source electrode 45A, a drain electrode 45B, and a third capacitance electrode 45D that are disposed at intervals; and the second wiring portion 45C is disposed in the non-display area 2000, the second wiring portion 45C is disposed to correspond to a first wiring portion 21A, and an orthographic projection of the third capacitance electrode 45D on the substrate 10 overlaps the orthographic projection of the second capacitance electrode 41B on the substrate 10.

The second metal layer 41 is made of, but is not limited to, an indium gallium zinc oxide; the third metal layer 43 and the fourth metal layer 45 are both made of, but are not limited to, at least one metal material consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), and tungsten (W).

Further, the step S20 includes: patterning the interlayer insulation layer 44 and the buffer layer 30 to form a first through hole 46A exposing a portion of the first conductor portion 41A2, a second through hole 46B exposing a portion of the second conductor portion 41A3, and a third through hole 46C exposing a portion of the first wiring portion 21A; and the first through hole 46A and the second through hole 46B penetrate the interlayer insulation layer 44, and the third through hole 46C penetrate the interlayer insulation layer 44 and the buffer layer 30.

In step S30, a passivation layer 50 and a planarization layer 60 are sequentially formed on a side of the thin-film transistor layer 40 away from the substrate 10. The passivation layer 50 is made of, but is not limited to, a single-layer silicon nitride (Si₃N₄), a single-layer silicon dioxide (SiO₂), a single-layer silicon oxynitride (SiONₓ), or a double-layer structure containing the above film layers; and the passivation layer 50 covers the source electrode 45A, the drain electrode 45B, the active layer 41A, and the gate insulation layer 42, thereby blocking water and oxygen from the source electrode 45A, the drain electrode 45B, and the active layer 41A and insulating the source electrode 45A, the drain electrode 45B, and the active layer 41A, which is as shown in FIG. 4B.

In step S40, a protective layer 70 is formed on a side of the planarization layer 60 away from the passivation layer 50. The protective layer 70 is an electrode layer 70 later.

Specifically, the step S40 includes steps as follows.

In step S41, the electrode layer 70 is formed on the side of the planarization layer 60 away from the passivation layer 50; an orthographic projection of the electrode layer 70 on the substrate 10 covers an orthographic projection of the planarization layer 60 on the substrate 10, as shown in FIG. 4C.

In step S42, a photoresist layer 73 is manufactured on the electrode layer 70, as shown in FIG. 4D.

In step S43, the photoresist layer 73 is exposed by using a first halftone mask, and then the photoresist layer 73 is developed to form a first photoresist sub-layer 73A and a second photoresist sub-layer 73B; and the first photoresist sub-layer 73A is disposed in the non-display area 2000, and the second photoresist sub-layer 73B is disposed in the light-emitting area 1100, as shown in FIG. 4E.

In step S44, the first photoresist sub-layer and the second photoresist sub-layer are used as a shielding layer, and a portion of the electrode layer 70 not shielded by the shielding layer is etched to form a first protective layer 71 and a second protective layer 72; and the first protective layer 71 is disposed to correspond to the first photoresist sub-layer 73A, and the second protective layer 72 is disposed to correspond to the second photoresist sub-layer 73B, as shown in FIG. 4F.

Specially, an orthographic projection of the first protective layer 71 on the thin-film transistor layer 40 at least overlaps a portion of an orthographic projection of the anode 81 on the thin-film transistor layer 40, and an orthographic projection of the second protective layer 72 on the thin-film transistor layer 40 covers the first wiring portion 21A and the second wiring portion 45C, thereby preventing water and oxygen from entering the wiring portion 40B and improving the reliability and service life of the display panel 1.

In step S45, the first photoresist sub-layer 73A and the second photoresist sub-layer 73B are peeled off.

Specifically, the step S40 further includes patterning the planarization layer 60 and the passivation layer 50 to form a fourth through hole 46D exposing a portion of the drain electrode 45B; and the fourth through hole 46D penetrates the planarization layer 60 and the passivation layer 50, as shown in FIG. 4G.

In step S50, an anode 81 is formed on a side of the protective layer 70 away from the planarization layer 60; wherein an orthographic projection of the anode 81 on the thin-film transistor layer 40 at least overlaps a portion of an orthographic projection of the protective layer 70 on the thin-film transistor layer 40.

Specifically, the anode 81 includes an overlapping portion 81A and a connecting portion 81B disposed at a peripheral side of the overlapping portion 81A, an orthographic projection of the overlapping portion 81A on the thin-film transistor layer 40 is located within or coincides with the orthographic projection of the first protective layer 71 on the thin-film transistor layer 40, and the connecting portion 81B is connected to the drain electrode 45B. It can be understood that, in the present embodiment, the first protective layer 71 is disposed between the planarization layer 60 and the anode 81, the orthographic projection of the overlapping portion 81A on the thin-film transistor layer 40 is located within or coincides with the orthographic projection of the first protective layer 71 on the thin-film transistor layer 40, the connecting portion 81B is connected to one of the source electrode 45A and the drain electrode 45B, and the first protective layer 71 can fill up the rough landform of the surface of the planarization layer 60, so that the contact between the anode 81 and the foreign matters on the planarization layer 60 can be avoided, and the risk of dark spots appearing on the display panel 1 is alleviated.

Specifically, in the present embodiment, the manufacturing method of the display panel 1 further includes steps as follows.

In step S60, a pixel define layer 90 is sequentially formed on a side of the anode 81 away from the protective layer 70, and then the pixel define layer 90 is patterned to form a first slot 90A exposing the anode 81 on the pixel define layer 90.

In step S70, a light-emitting layer 82 and a cathode 83 are sequentially formed on a side of the anode 81 away from the pixel define layer 90, as shown in FIG. 1.

The present embodiment provides a display device, and the display device includes the display panel described in any one of the above embodiments.

It can be understood that the display panel has been described in detail in the above embodiments, and is not repeated here.

In a specific application, the display device can be a display screen of devices such as a smartphone, a tablet, a laptop, a smart wristband, a smart watch, smart glasses, a smart helmet, a desktop computer, a smart television, or a digital camera, or can even be applied to an electronic device having a flexible display screen.

In summary, the present disclosure provides the display panel and the manufacturing method thereof, and the display device. The display panel includes the display area and the non-display area disposed adjacent to the display area; the display panel includes the substrate, and the thin-film transistor layer, the passivation layer, the planarization layer, the protective layer, and the anode that are disposed and stacked on the substrate; the thin-film transistor layer includes the wiring portion disposed in the non-display area, and the orthographic projection of the protective layer on the thin-film transistor layer at least covers the wiring portion. By providing the protective layer between the planarization layer and the anode and making the orthographic projection of the protective layer on the thin-film transistor layer at least overlaps with the portion of the orthographic projection of the anode on the thin-film transistor layer, the anode is thereby prevented from contacting with foreign matters on the planarization layer, alleviating a risk of dark spots appearing on the display panel.

In the above embodiments, the description of each embodiment has its own emphasis, and parts of the embodiments that are not described in detail in some embodiments may refer to the related description of other embodiments.

The display panel and the manufacturing method thereof, and the display device provided by the embodiments of the present disclosure are described in detail. Illustrated embodiments are used herein to describe the principles and the embodiments of the present disclosure, and the description of the illustrated embodiments is merely used to help understand the manufacturing method of the present disclosure and the core idea thereof. Meanwhile, for those skilled in the related art, according to the core idea of the present disclosure, there will be changes in the specific implementation modes and application scope. In summary, the content of the present specification should not be construed as limiting the present disclosure.

What is claimed is:

1. A display panel, comprising a display area and a non-display area disposed adjacent to the display area, wherein the display panel comprises:
a substrate;
a thin-film transistor layer, disposed on the substrate;
a passivation layer, disposed on the thin-film transistor layer;
a planarization layer, disposed on a side of the passivation layer away from the thin-film transistor layer;
a protective layer, disposed on a side of the planarization layer away from the passivation layer; and
an anode, disposed on a side of the protective layer away from the planarization layer; and
wherein an orthographic projection of the protective layer on the thin-film transistor layer at least overlaps a portion of an orthographic projection of the anode on the thin-film transistor layer.

2. The display panel according to claim 1, wherein the thin-film transistor layer comprises a wiring portion disposed in the non-display area;
wherein the protective layer comprises a first protective layer and a second protective layer disposed at intervals; and the first protective layer is disposed in the display area, and the second protective layer is disposed in the non-display area; and
wherein an orthographic projection of the first protective layer on the thin-film transistor layer at least overlaps a portion of the orthographic projection of the anode on the thin-film transistor layer, and an orthographic projection of the second protective layer on the thin-film transistor layer covers the wiring portion.

3. The display panel according to claim 2, wherein the thin-film transistor layer comprises an active layer, a gate insulation layer, a gate electrode, an interlayer insulation layer, a source electrode, and a drain electrode that are disposed and stacked on the substrate; and
wherein the anode comprises an overlapping portion and a connecting portion disposed at a peripheral side of the overlapping portion, an orthographic projection of the overlapping portion on the thin-film transistor layer is located within or coincides with the orthographic projection of the first protective layer on the thin-film transistor layer, and the connecting portion is connected to the source electrode or the drain electrode.

4. The display panel according to claim 2, wherein the thin-film transistor layer comprises a gate electrode, a gate insulation layer, an active layer, a source electrode, and a drain electrode that are disposed and stacked on the substrate; and
wherein the orthographic projection of the first protective layer on the thin-film transistor layer is located within or coincides with the orthographic projection of the anode on the thin-film transistor layer, and the first protective layer is connected to the source electrode or the drain electrode.

5. The display panel according to claim 2, wherein a side of the first protective layer close to the planarization layer is flush with a side of the first protective layer close to the anode.

6. The display panel according to claim 1, wherein the protective layer is made of an inert material; and the inert material is at least one selected from the group consisting of a molybdenum-titanium-nickel compound, a titanium metal, an indium gallium titanium oxide, and a zinc oxide.

7. The display panel according to claim 1, wherein a thickness of the protective layer is greater than or equal to 100 angstroms and less than or equal to 400 angstroms.

8. A manufacturing method of a display panel, wherein the display panel comprises a display area and a non-display area disposed adjacent to the display area, and the manufacturing method of the display panel comprises steps as follows:
providing a substrate;
forming a thin-film transistor layer on the substrate;
sequentially forming a passivation layer and a planarization layer on a side of the thin-film transistor layer away from the substrate;
forming a protective layer on a side of the planarization layer away from the passivation layer; and
forming an anode on a side of the protective layer away from the planarization layer;
wherein an orthographic projection of the anode on the thin-film transistor layer at least overlaps a portion of an orthographic projection of the protective layer on the thin-film transistor layer.

9. The manufacturing method of the display panel according to claim 8, wherein the display area comprises a light-emitting area and a non-light-emitting area disposed adjacent to the light-emitting area; and
wherein the forming the protective layer on the side of the planarization layer away from the passivation layer comprises steps as follows:
forming an electrode layer on a side of the planarization layer away from the passivation layer;
manufacturing a photoresist layer on the electrode layer;
exposing the photoresist layer by using a first halftone mask, and then developing the photoresist layer to form a first photoresist sub-layer and a second photoresist sub-layer, wherein the first photoresist sub-layer is disposed in the non-display area, and the second photoresist sub-layer is disposed in the light-emitting area;
using the first photoresist sub-layer and the second photoresist sub-layer as a shielding layer, and etching a portion of the electrode layer not shielded by the shielding layer to form a first protective layer and a second protective layer, wherein the first protective layer is disposed to correspond to the first photoresist sub-layer, and the second protective layer is disposed to correspond to the second photoresist sub-layer; and
peeling off the first photoresist sub-layer and the second photoresist sub-layer.

10. A display device, comprising a display panel, wherein the display panel comprises a display area and a non-display area disposed adjacent to the display area, and the display panel further comprises:
a substrate;
a thin-film transistor layer, disposed on the substrate;
a passivation layer, disposed on the thin-film transistor layer;
a planarization layer, disposed on a side of the passivation layer away from the thin-film transistor layer;
a protective layer, disposed on a side of the planarization layer away from the passivation layer; and
an anode, disposed on a side of the protective layer away from the planarization layer; and
wherein an orthographic projection of the protective layer on the thin-film transistor layer at least overlaps a portion of an orthographic projection of the anode on the thin-film transistor layer.

11. The display device according to claim 10, wherein the thin-film transistor layer comprises a wiring portion disposed in the non-display area;
wherein the protective layer comprises a first protective layer and a second protective layer disposed at intervals; and the first protective layer is disposed in the display area, and the second protective layer is disposed in the non-display area; and
wherein an orthographic projection of the first protective layer on the thin-film transistor layer at least overlaps a portion of the orthographic projection of the anode on the thin-film transistor layer, and an orthographic projection of the second protective layer on the thin-film transistor layer covers the wiring portion.

12. The display device according to claim 11, wherein the thin-film transistor layer comprises an active layer, a gate insulation layer, a gate electrode, an interlayer insulation layer, a source electrode, and a drain electrode that are disposed and stacked on the substrate; and
wherein the anode comprises an overlapping portion and a connecting portion disposed at a peripheral side of the overlapping portion, an orthographic projection of the overlapping portion on the thin-film transistor layer is located within or coincides with the orthographic projection of the first protective layer on the thin-film transistor layer, and the connecting portion is connected to the source electrode or the drain electrode.

13. The display device according to claim 11, wherein the thin-film transistor layer comprises a gate electrode, a gate insulation layer, an active layer, a source electrode, and a drain electrode that are disposed and stacked on the substrate; and
wherein the orthographic projection of the first protective layer on the thin-film transistor layer is located within or coincides with the orthographic projection of the anode on the thin-film transistor layer, and the first protective layer is connected to the source electrode or the drain electrode.

14. The display device according to claim 11, wherein a side of the first protective layer close to the planarization layer is flush with a side of the first protective layer close to the anode.

15. The display device according to claim 10, wherein the protective layer is made of an inert material; and the inert material is at least one selected from the group consisting of a molybdenum-titanium-nickel compound, a titanium metal, an indium gallium titanium oxide, and a zinc oxide.

16. The display device according to claim 10, wherein a thickness of the protective layer is greater than or equal to 100 angstroms and less than or equal to 400 angstroms.
